(19) United States
(12) Patent Application Publication
(10) Pub. No.: US 2014/0027163 A1
(43) Pub. Date: Jan. 30, 2014

(54) PRINTED CIRCUIT BOARD AND METHOD FOR MANUFACTURING THE SAME

(71) Applicant: SAMSUNG ELECTRO-MECHANICS CO., LTD., SUWON (KR)

(72) Inventors: TAE HONG MIN, SUWON (KR); SUK HYEON CHO, SUWON (KR); JONG RIP KIM, SUWON (KR); JUNG HAN LEE, SUWON (KR)

(73) Assignee: SAMSUNG ELECTRO-MECHANICS CO., LTD., SUWON (KR)

(21) Appl. No.: 13/951,886

(22) Filed: Jul. 26, 2013

(30) Foreign Application Priority Data
Jul. 30, 2012 (KR) 10-2012-0083160
Dec. 5, 2012 (KR) 10-2012-0140480
May 29, 2013 (KR) 10-2013-0061168

(51) Int. Cl. H05K 1/02; H05K 3/00; H05K 3/10

(52) U.S. Cl. CPC H05K 1/0271; H05K 3/10; H05K 3/0094
USPC 174/257; 427/97.2; 156/280; 205/183; 174/250; 174/258; 174/266; 174/262

(57) ABSTRACT

Disclosed herein are a printed circuit board and a method for manufacturing the same. The printed circuit board includes: a core reinforcement having stiffness; insulating layers formed on both surfaces of the core reinforcement; a through hole formed by penetrating through the insulating layer and the core reinforcement; and a circuit layer formed on the insulating layer and a plating layer formed in the through hole for implementing inter-layer connection of the circuit layers.

This application claims the benefit under 35 U.S.C. Section 119 of Korean Patent Application Serial Nos. 10-2012-0083160, 10-2012-0140480, and 10-2013-0061168 entitled “Printed Circuit Board And Method For Manufacturing The Same” filed on Jul. 30, 2012, Dec. 5, 2012 and May 29, 2013, which is hereby incorporated by reference in its entirety into this application.

### BACKGROUND OF THE INVENTION

1. Technical Field

The present invention relates to a printed circuit board and a method for manufacturing the same.

2. Description of the Related Art

In recent, as a thickness of portable devices have become thin, attempts to reduce a thickness of all the internal components by making a board having a plurality of electronic components mounted thereon thin and making electronic components mounted in the portable devices thin have been conducted.

In particular, when the board having the electronic components mounted thereon is manufactured in a thin plate type, the board is exposed to high temperature during a process of manufacturing the board, a reflow process at the time of mounting the electronic components, or the like and is repeatedly subjected to high temperature processing or cooling, such that the board may be warped due to natures of a material thereof.

In order to prevent warpage of the board, attempts to reduce a difference between coefficients of thermal expansion (CTE) of raw materials have been conducted to increase stiffness of raw materials used during the process of manufacturing the board and improve the warpage due to the difference between the CTEs at the time of the reflow process. Therefore, a necessity of the technology development thereof has more increased.

Further, as a method for preventing the warpage of the board by improving a physical structure of the board during the process of manufacturing the board, in order to increase stiffness of a core material of the board, a method for further inserting a metallic reinforcement into the board has been reviewed; however, since the reinforcement is a metallic material, there is a need to remove a specific portion of the metallic reinforcement in advance so as to form vias, etc., for electrically connecting circuit patterns.

However, in order to form the vias, etc., in the metallic reinforcement, the metallic core material, or the like, there is a need to remove the metallic reinforcement by using an etching process or a laser. In this case, a process of providing a separate carrier, forming an insulating layer on the metallic reinforcement on the carrier, and removing the carrier needs to be performed so as to process the metallic reinforcement, which may lead to the increase in manufacturing costs of the board.

Further, in case of the related art using the metallic reinforcement, as a portion of the metallic reinforcement is removed in advance at a position through which the through hole passes so as to prevent the through hole from contacting the metallic reinforcement and then the insulating layer is applied on a surface including the through hole, it may be difficult to form the through hole of a fine pitch at the time of forming circuit wirings.

### RELATED ART DOCUMENT

### Patent Document

(Patent Document 1) Japanese Patent Laid-open Publication No. 2004-193295

### SUMMARY OF THE INVENTION

An object of the present invention is to provide a printed circuit board for preventing warpage from occurring.

Another object of the present invention is to provide a method for manufacturing a printed circuit board capable of minimizing the occurrence of warpage of a board during a process of manufacturing a printed circuit board.

According to an exemplary embodiment of the present invention, there is provided a printed circuit board, including: a core having insulating layers and a core reinforcement alternately laminated therein.

The core may be configured so that the core reinforcement is inserted between the insulating layers and the core reinforcement is laminated on both surfaces of the insulating layer.

The core reinforcement may be made of a plate-shaped glass material and may be formed in a film type of a non-conductive polymer material.

A portion of a thickness of the core reinforcement to the overall thickness of the core may range from 35% to 80% and the core may be configured to satisfy the following Equation for a warpage characteristic in relationship to a coefficient of thermal expansion (CTE) and a modulus of elasticity between the core reinforcement and the insulating layer.

$$\frac{( α1 + α2 )}{( E 1 \times V 1 ) + ( E 2 \times ( 1 - V 1 ) )} = 6.492 \times {10}^{- 8} \sim 4.463 \times {10}^{- 6} / GPa \cdot k \qquad Equation$$

where

α1: Coefficient of thermal expansion of the core reinforcement (1/k),

α2: Coefficient of thermal expansion of the insulating layer (1/k),

E1: Modulus of elasticity of the core reinforcement (GPa),

E2: Modulus of elasticity of the insulating layer (GPa).

According to another exemplary embodiment of the present invention, there is provided a printed circuit board, including: a core reinforcement having stiffness; insulating layers formed on both surfaces of the core reinforcement; a through hole formed by penetrating through the insulating layer and the core reinforcement; and a circuit layer formed on the insulating layer and a plating layer formed in the through hole for implementing inter-layer connection of the circuit layers.

According to another exemplary embodiment of the present invention, there is provided a method for manufacturing a printed circuit board, including: preparing a core reinforcement; forming insulating layers on both surfaces of the core reinforcement; forming a through hole penetrating through the core reinforcement and the insulating layers; and forming a plating layer in the through hole and forming a circuit layer on a surface of the insulating layer.

According to another exemplary embodiment of the present invention, there is provided a printed circuit board, including: an insulating layer; core reinforcements laminated on both surfaces of the insulating layer; a through hole formed by penetrating through the insulating layer and the core reinforcement; and a circuit layer formed on the core reinforcement.

According to another embodiment of the present invention, there is provided a method for manufacturing a printed circuit board, including: bonding core reinforcements to both surfaces of an insulating layer; forming a seed layer on the core reinforcement; forming a plating resist layer having an opening for forming a circuit on the seed layer; forming a plating layer in the opening for forming the circuit; and forming the circuit layer by removing the plating resist layer.

### BRIEF DESCRIPTION OF THE DRAWINGS

FIG. 1 is a cross-sectional view of a printed circuit board according to a first exemplary embodiment of the present invention.

FIGS. 2 to 5 are process cross-sectional views of a method for manufacturing a printed circuit board according to the first exemplary embodiment of the present invention.

FIG. 2 is a cross-sectional view of a core reinforcement.

FIG. 3A is a cross-sectional view of a structure in which an insulating layer is laminated on the core reinforcement.

FIG. 3B is a cross-sectional view of a structure in which a coating layer is inserted between the core reinforcement and the insulating layer.

FIG. 3C is a cross-sectional view of a structure in which a metal thin film is formed on the insulating layer.

FIG. 4 is a cross-sectional view of a structure in which a through hole is formed.

FIG. 5 is a cross-sectional view of a structure in which a circuit layer is formed on the insulating layer and a plating layer is formed within the through hole.

FIG. 6 is a cross-sectional view of a printed circuit board according to a second exemplary embodiment of the present invention.

FIGS. 7 to 12 are process cross-sectional views of a method for manufacturing a printed circuit board according to the second exemplary embodiment of the present invention.

FIG. 7 is a cross-sectional view of a structure in which a core reinforcement is laminated on an insulating layer.

FIG. 8 is a cross-sectional view of a structure in which a through hole is formed.

FIG. 9 is a cross-sectional view in which seed layers are formed on a surface of the core reinforcement and an inner wall of the through hole.

FIG. 10 is a cross-sectional view of a structure in which a plating resist layer is formed.

FIG. 11 is a cross-sectional view of a structure in which a plating layer is formed.

FIG. 12 is a cross-sectional view of a structure in which a circuit layer is formed.

FIG. 13 is a cross-sectional view of a multilayer printed circuit board in which a plurality of insulating layers and a plurality of circuit layers are built up on the printed circuit board according to the exemplary embodiment of the present invention.

FIG. 14 is a warpage characteristic simulation graph of the printed circuit board according to the first exemplary embodiment of the present invention and the printed circuit board according to the related art.

FIG. 15 is a stiffness characteristic simulation graph of the printed circuit board according to the first and second exemplary embodiments of the present invention.

FIG. 16 is a warpage characteristic simulation graph of the printed circuit board according to the first and second exemplary embodiments of the present invention.

### DESCRIPTION OF THE PREFERRED EMBODIMENTS

The acting effects and technical configuration with respect to the objects of a printed circuit board and a method for manufacturing the same according to the present invention will be clearly understood by the following description in which exemplary embodiments of the present invention are described with reference to the accompanying drawings.

Further, when it is determined that the detailed description of the known art related to the present invention may obscure the gist of the present invention, the detailed description thereof will be omitted. In the description, the terms “first”, “second”, and so on are used to distinguish one element from another element, and the elements are not defined by the above terms.

### First Exemplary Embodiment

### Printed Circuit Board

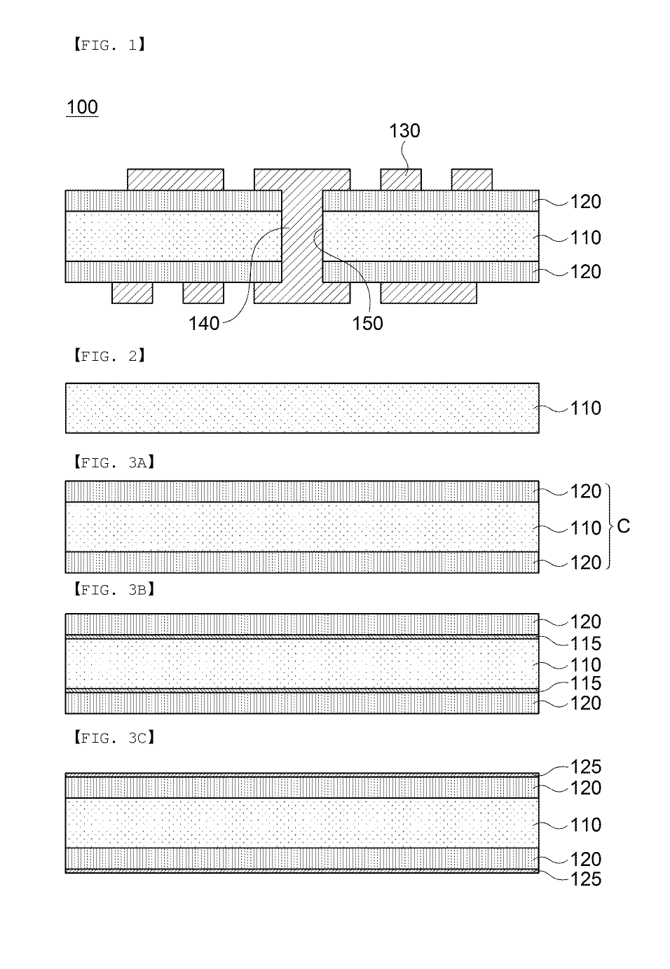

First, FIG. 1 is a cross-sectional view of a printed circuit board according to a first exemplary embodiment of the present invention.

As illustrated in FIG. 1, a printed circuit board 100 according to the first exemplary embodiment of the present invention may be configured to include a core reinforcement 110, a core C including insulating layers 120 formed on both surfaces of the core reinforcement 110, and circuit layers 130 formed on the insulating layers 120.

In this configuration, the printed circuit board 100 is provided with a through hole 150 which simultaneously penetrates through the core reinforcement 110 and the insulating layer 120 and the circuit layer 130 may be formed on the insulating layer 120 and a plating layer 140 may be formed in the through hole 150.

A coating layer (not illustrated) may be further disposed between the core reinforcement 110 and the insulating layer 120 to reinforce adhesion between a surface of the core reinforcement 110 and the insulating layer 120. The coating layer may increase an ionization-OH group by performing plasma treatment on the surface of the core reinforcement 110 to increase the adhesion between the core reinforcement 110 and the insulating layer 120 and may be formed by applying a coupling agent, and the like, to secure the adhesion therebetween.

In this case, the coating layer may be preferably formed at a thickness of about 2 μm or less.

Herein, the core reinforcement 110 may be glass or a non-conductive polymer material. As the glass, a plate-shaped glass be used and formed at a thickness of about 25 to 200 μm in proportion to the overall thickness of the printed circuit board.

The reason for limiting the thickness of glass used as the core reinforcement 110 to 25 to 200 μm is that a predetermined warpage may occur during a process of manufacturing a printed circuit board and the core reinforcement may reliably withstand from being damaged when a radius of curvature of warpage is 10 cm or less in a range in which the thickness of glass is 25 to 200 μm.

When the glass is used as the core reinforcement 110, a glass material having thermal conductivity of about 0.6 W/mK may be preferably used and a glass material having thermal conductivity of 1.0 W/mK or more may be more preferably used to prevent local thermal stress.

As such, when the glass material is used as the core reinforcement 110, the glass material has a high elastic module of 50 GPa or more, thereby preventing the warpage occurring during the process of manufacturing a printed circuit board.

Further, the core reinforcement 110 may also be formed in a film type of a non-conductive polymer material, instead of the glass.

The insulating layers 120 formed on both surfaces of the core reinforcement 110 may include several strands of glass fabric to maintain the elastic module capable of coping with the warpage separately from the core reinforcement 110.

Therefore, the insulating layer 120 may be formed in a film type or an insulating sheet in which a glass fabric is included.

When the insulating layer 120 is formed of the insulating sheet, the insulating sheets are laminated on both surfaces of the core reinforcement 110 and the insulating sheet may be bonded to the surface of the core reinforcement 110 by applying heat and pressure to the upper surface of the insulating sheet to compress the insulating sheet.

The exemplary embodiment of the present invention illustrates that the insulating layers 120 are formed on both surfaces of the core reinforcement 110, but is not limited thereto. Therefore, the insulating layer 120 may be formed only on one surface of the core reinforcement 110.

Further, the core reinforcement 110 formed with the insulating layer 120 is provided with the through hole 150 which penetrates through the insulating layer 120 and the core reinforcement 110 and the plating layer 140 may be formed in the through hole 150 and the circuit layer 130 may be formed on the insulating layer 120. The circuit layer 130 and the plating layer 140 may be formed by electrolytic copper plating, the circuit layer 130 formed on the insulating layer 120 may form a circuit pattern, and the plating layer 140 formed in the through hole 150 may be formed as an inter-layer connection layer which electrically connects the circuit layer 130 formed on the insulating layer 120.

Further, a thin metal thin film (not illustrated) of 2 μm or less may be further formed on the insulating layer 120. The metal thin film may be mainly formed of a copper foil and may be simultaneously formed at the time of applying the insulating layer 120 on the core reinforcement 110.

The metal thin film is used as a seed layer at the time of performing the electrolytic copper plating for forming the circuit layer 130 and needs to be formed at a thickness of 2 μm or less to be able to be subjected to laser processing for forming the through hole 150 which penetrates through the insulating layer 120 and the core reinforcement 110. Further, the metal thin film may be made of a conductive carbon material.

### First Exemplary Embodiment

### Method for Manufacturing Printed Circuit Board

Meanwhile, a method for manufacturing a printed circuit board according to the exemplary embodiment of the present invention will be described below with reference to FIGS. 2 to 5.

First, as illustrated in FIG. 2, the core reinforcement 110 is prepared. The core reinforcement 110 may be a plate-shaped glass or a non-conductive polymer material. In the case of the non-conductive polymer material, the core reinforcement may be formed in a film type.

Herein, in the case of glass, the core reinforcement 110 preferably has the elastic module of 50 GPa or more and is formed at a thickness of 25 to 200 μm and when the thickness is maintained, the core reinforcement may be deformed with a predetermined radius of curvature and then may be recovered to an original state without being damaged, during the process of manufacturing a printed circuit board.

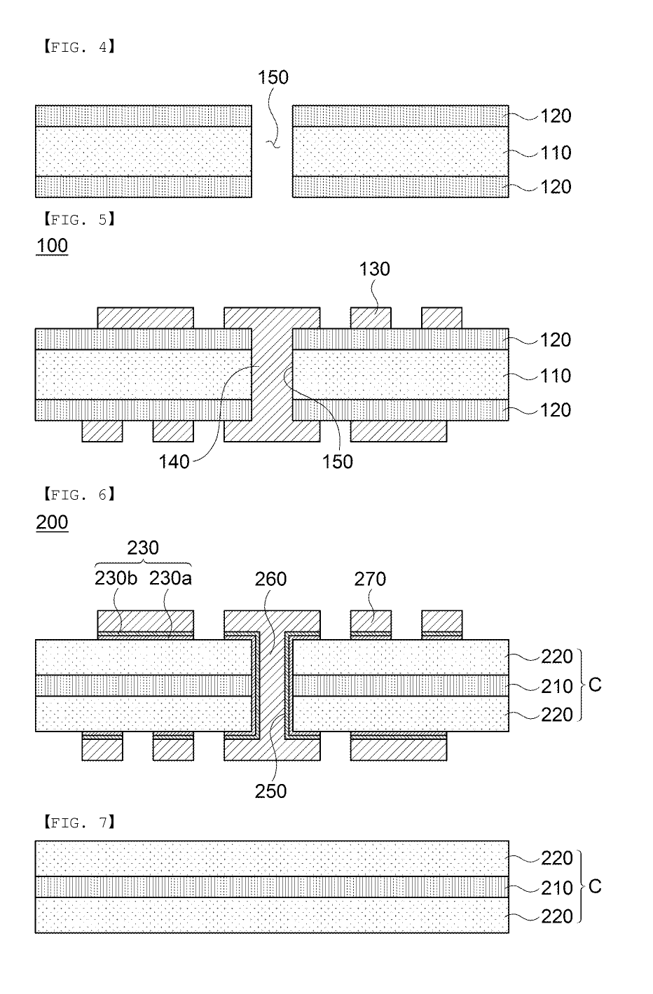

Next, as illustrated in FIG. 3A, the core C may be manufactured by forming the insulating layers 120 on both surfaces of the core reinforcement 110. The insulating layer 120 is formed by applying an insulating material on the core reinforcement 110. For example, an insulating material added with the glass fabric material may also be applied on the core reinforcement 110.

In this case, as illustrated in FIG. 3B, the coating layer (s) 115 may be further formed on one surface or both surfaces of the core reinforcement 110, prior to forming the insulating layer 120. The coating layer 115, which is a thin insulating layer for reinforcing adhesion between the core reinforcement 110 and the insulating layer 120, is mainly applied with a polymer material to improve the adhesive performance of the insulating layer 120. The coating layer 115 is preferably formed at a thickness of about 2 μm and may increase a —OH group by performing plasma treatment on the surface of the core reinforcement 110 to increase the adhesion.

Further, the coating layer 115 may be formed by applying a coupling agent, and the like, on the surface of the core reinforcement 110, in addition to performing the plasma treatment on the surface of the core reinforcement 110.

Next, as illustrated in FIG. 4, the through hole 150 penetrating through the core reinforcement 110 and the insulating layer 120 may be formed. The through hole 150 may be mainly formed by the laser processing and processed by using a CO₂ laser. As the core reinforcement 110 and the insulating layer 120 which are made of an insulating material is formed by laser irradiation, as in the related art, a separate insulating substrate for preventing inter-layer conduction need not to be formed on an inner wall surface of the through hole 150 and as the through hole is formed only by the laser processing, the through hole 150 having a fine pitch may be processed.

Meanwhile, prior to forming the through hole in the core reinforcement 110 and the insulating layer 120, as illustrated in FIG. 3C, the thin metal thin film 125 having a thickness of about 2 μm may be further formed on the insulating layer 120. The metal thin film 125 may be mainly formed of a copper foil and since the thickness thereof is formed to be thick enough to be subjected to the laser processing (subjected to the CO₂ laser processing at a thickness of 5 μm or less), the through hole 150 may be processed by the CO₂ laser irradiation.

In this case, the metal thin film 125 formed on the insulating layer 120 in addition to a portion at which the through hole 150 is formed may be used as a seed layer at the time of the copper plating for forming the circuit layer at the following process.

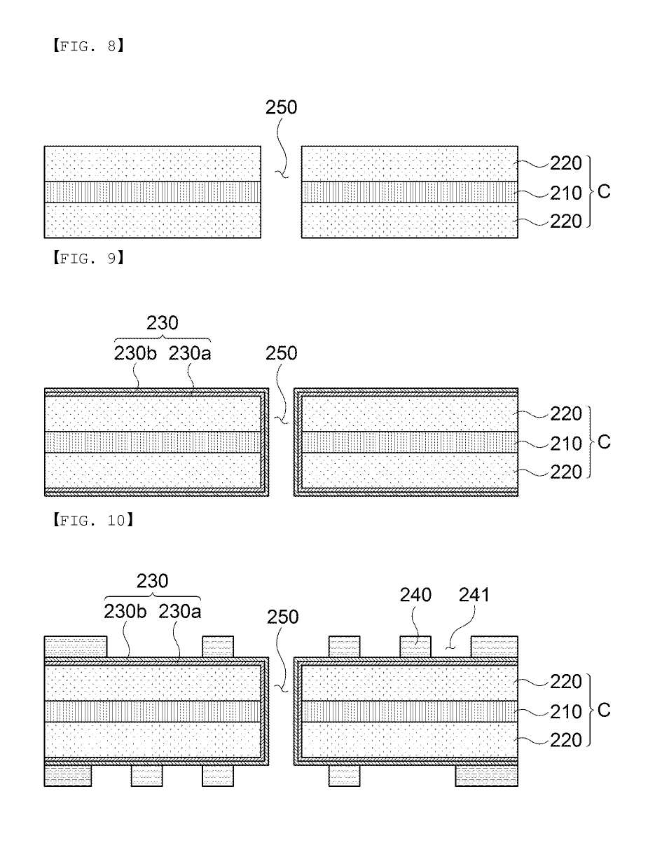

Next, as illustrated in FIG. 5, the plating layer 140 may be formed in the through hole 150 and the circuit layer 130 may be formed on the insulating layer 120. Among the plating layer 140 and the circuit layer 130, the circuit layer 130 formed on the insulating layer 120 may be formed in a circuit pattern and the plating layer 140 formed in the through hole 150 may be formed as the inter-layer connection layer which electrically connects the circuit layer 130 formed on the insulating layer 120 forming the circuit pattern.

The circuit layer 130 and the plating layer 140 may be formed by the electrolytic copper plating and may be simultaneously formed on the insulating layer 120 and in the through hole 150.

### Second Exemplary Embodiment

### Printed Circuit Board

Meanwhile, FIG. 6 is a cross-sectional view of a printed circuit board according to a second exemplary embodiment of the present invention.

As illustrated in FIG. 6, a printed circuit board 200 according to the second exemplary embodiment of the present invention may be configured to include an insulating layer 210, a core C including a core reinforcement 220 formed on an insulating layer 210, and a circuit layer 270 formed on the core C.

In this case, like the insulating layer applied to the printed circuit board according to the first exemplary embodiment of the present invention as described above, the insulating layer 210 may be made of an insulating material in which several strands of glass fabric is included and may be formed in a film type or an insulating sheet with which a glass fabric is mixed.

As illustrated in FIG. 6, the core reinforcement 220 may be bonded to both surfaces of the insulating layers 210, which is only one exemplary embodiment, and the core reinforcement 220 may be bonded only to one surface of the insulating layer 210.

As the core reinforcement 220, glass having an elastic module of about 50 GPa or more may be used and thin plate-shaped glasses may be each laminated on the upper and lower surfaces of the insulating layer 210. Further, the core reinforcement 220 may be formed in a film type of a non-conductive polymer material, instead of the glass.

As described above, when the core reinforcements 220 of the plate-shaped glass are formed on both surfaces of the insulating layer 210, having the insulating layer 210 therebetween, the insulating layer 210 between the core reinforcements 220 serves to absorb impact, thereby preventing the core reinforcement 220 from being damaged during the process of manufacturing a printed circuit board.

Here, FIG. 6 illustrates that the insulating layer 210 laminated between the core reinforcements 220 is configured of a single layer, which is to describe only one exemplary embodiment. Therefore, the insulating layer may be formed in a multilayer of at least two layers.

The circuit layer 270 may be formed on the core reinforcement 220 in a predetermined pattern and similar to the first exemplary embodiment of the present invention, the circuit layer 270 formed on the core reinforcement 220 may be inter-layer connected by the plating layer 260 filled in the through hole 250 formed by penetrating through the core reinforcement 220 and the insulating layer 210.

The circuit layer 270 may be formed on the core reinforcement 220 by the plating layer and at the time of forming the plating layer for forming the circuit layer 270, the seed layer 230 is first formed, and then the plating layer may be formed and the circuit layer 270 may be formed by the patterning of the plating layer. In this case, the seed layer 230 may be formed of a first seed layer 230a and a second seed layer 230b.

The seed layer 230 including the first seed layer 230a and the second seed layer 230b may be made of any one selected from the group consisting of titanium (Ti), copper (Cu), molybdenum (Mo), nickel (Ni), silver (Ag), zinc (Zn), and carbon (C), and the like, or an alloy thereof.

Further, the seed layer 230 and the circuit layer 270 may be made of copper (Cu) in consideration of advantages of costs, a process, and the like.

According to the printed circuit board 200 configured according to the exemplary embodiment of the present invention, since the core reinforcements 220 based on the insulating layer 210 are made of the plate-shaped glass, the circuit layer 270 formed on the core reinforcement 220 is formed on a smooth surface, and thus there is no roughness at an interface between the core reinforcement 220 and the circuit layer 270, thereby easily implementing the circuit layer 270 having less signal noise and an ultra fine pitch.

Since the circuit layer 270 has a smooth surface, that is, small surface roughness, an etching amount for forming the circuit layer is reduced and a loss amount at the time of forming the circuit is reduced, thereby forming the ultra fine pitch and remarkably reducing the signal noise.

### Second Exemplary Embodiment

### Method For Manufacturing Printed Circuit Board

Next, FIGS. 7 to 12 are process cross-sectional views sequentially illustrating a method for manufacturing a printed circuit board according to a second exemplary embodiment of the present invention.

First, as illustrated in FIG. 7, the core C may be manufactured by bonding the core reinforcements to the upper and lower surfaces of the insulating layer 210. In this case, the insulating layer 210 may be made of an insulating material impregnated with a glass fabric as a polymer material having heat resistance and may be formed of a film type or an insulating sheet with which the glass fabric is mixed. Further, the insulating layer 210 laminated between the core reinforcements absorbs impact that occurs during the process to prevent the core reinforcements 220 from being damaged due to impact or warpage.

The manufacturing of the core C may further include laminating the core reinforcements 220 on both surfaces of the insulating layer 210, sequentially laminating the core reinforcements 220 and the insulating layer 210, and heating and pressing the core reinforcements 220 and the insulating layer 210 to bond the core reinforcements 220 to both surfaces of the insulating layer 210.

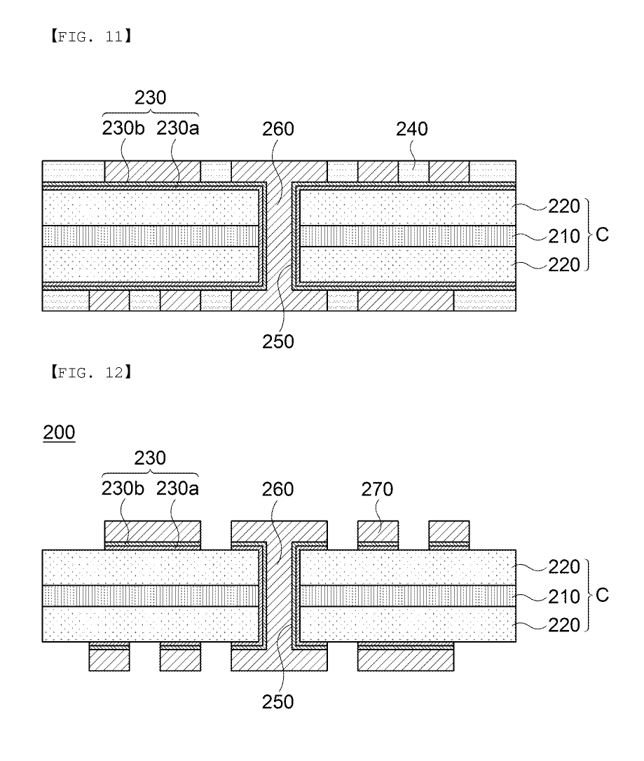

Next, as illustrated in FIG. 8, the through hole 250 penetrating through the core C in which the insulating layer 210 and the core reinforcements 220 are laminated may be formed. The through hole 250 may be formed by laser drilling, representatively, a CO₂ laser, a YAG laser, a pulse UV excimer laser, and the like.

Meanwhile, after the forming of the through hole 250 in the core C, cleaning the surface of the core C forming the through hole 250 and an inner wall of the through hole 250 may be further provided. In this case, for cleaning the surface of the core C and the inner wall of the through hole 250, no particular one process is used, and therefore the dry etching or the wet etching may be used and the desmear process may also be used. Among others, as the dry etching process, plasma etching, sputter etching, ion etching, and the like, may be used.

Next, as illustrated in FIG. 9, the seed layer 230 may be formed on the surface of the core C including the inner wall of the through hole 250. The seed layer 230 is to facilitate the growth of the plating layer at the time of forming the plating layer for forming the circuit layer 270 in the following process and may be mainly formed by a sputtering method. Further, as the seed layer 230 may be formed by being divided into the first seed layer 230a and the second seed layer 230b, if necessary and may be made of any one selected from the group consisting of titanium (Ti), copper (Cu), molybdenum (Mo), nickel (Ni), silver (Ag), zinc (Zn), and carbon (C), and the like, or an alloy thereof.

Next, as illustrated in FIG. 10, a plating resist layer 240 having an opening 241 for forming the circuit on the seed layer 230 may be formed. The plating resist layer 240 may be formed using a photo resist using a photosensitive polymer and the opening 241 for forming the circuit may be formed using a mask after the photo resist is applied. In this case, the opening 241 for forming the circuit of the plating resist layer 240 may be formed depending on design specifications of the circuit patterns.

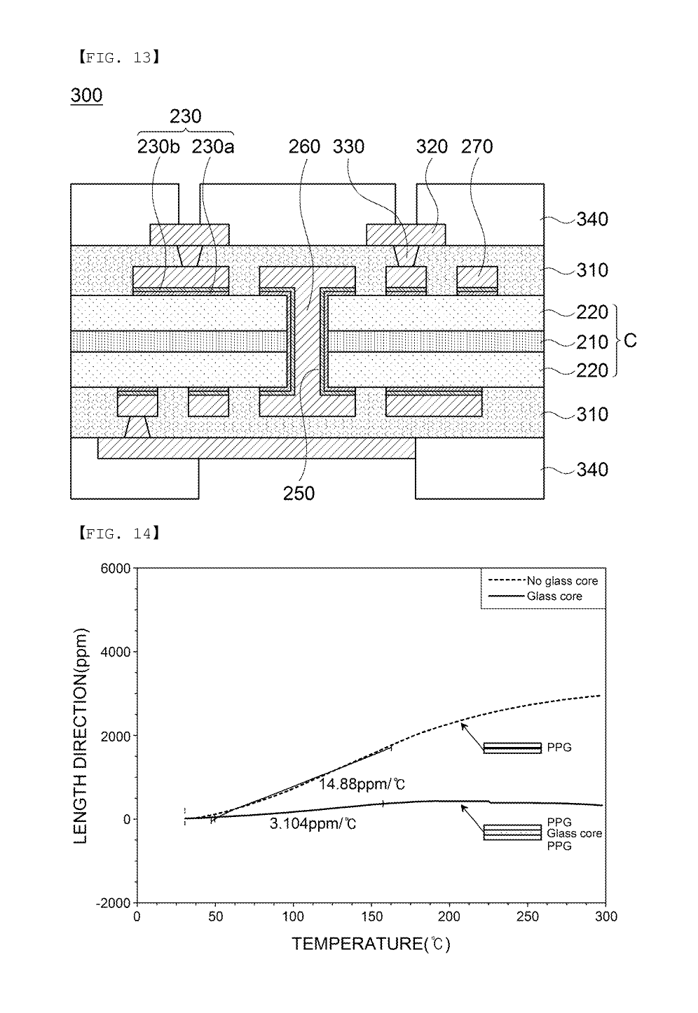

Next, as illustrated in FIGS. 11 and 12, the plating layer 260 is formed on the core reinforcement 220 formed with the plating resist layer 240 and the circuit layer 270 may be formed by removing the plating resist layer 240.

Here, the plating process of forming the plating layer 260 on the core reinforcement 220 may be performed by electroplating and may be preferably made of copper (Cu). Further, the removing of the plating resist layer 240 may be performed by a mechanical delamination process and a chemical delaminating process using a chemical solution.

According to the printed circuit boards 100 and 200 configured according to the first and second exemplary embodiments of the present invention, as illustrated in FIG. 13, the core reinforcements 220 are formed on the insulating layers 210 or a build up process of continuously laminating the second insulating layer 310 and the circuit layer 270 on the upper and lower surfaces of the core C having a configuration in which the core reinforcements 220 are laminated on both surfaces of the insulating layer 210 may be performed subsequently.

FIG. 13 is a cross-sectional view of a multilayer printed circuit board in which a plurality of insulating layers and a plurality of circuit layers are built up on the printed circuit board according to the exemplary embodiment of the present invention.

A multilayer printed circuit board 300 illustrated in FIG. 13 may be manufactured by laminating second insulating layers 310 made of prepreg (PPG) on the upper and lower surfaces of the core C, respectively, in which the insulating layer 210 and the core reinforcement 220 are laminated and forming the circuit layer 320 on the second insulating layer 310, after manufacturing the printed circuit board illustrated in FIGS. 1 and 6. The second insulating layer 310 laminated in the core C is provided with via holes 330 to conduct the circuit layer 270 formed on the core C and the circuit layer 270 formed on the second insulating layer 310, thereby implementing the inter-layer connection of the circuit layers, and the solder resist layer 340 is formed on the second insulating layer 310 to protect and expose the second insulating layer 310 and the circuit layer 270.

Stiffness and Warpage Characteristic for Each Exemplary Embodiment of Printed Circuit Board

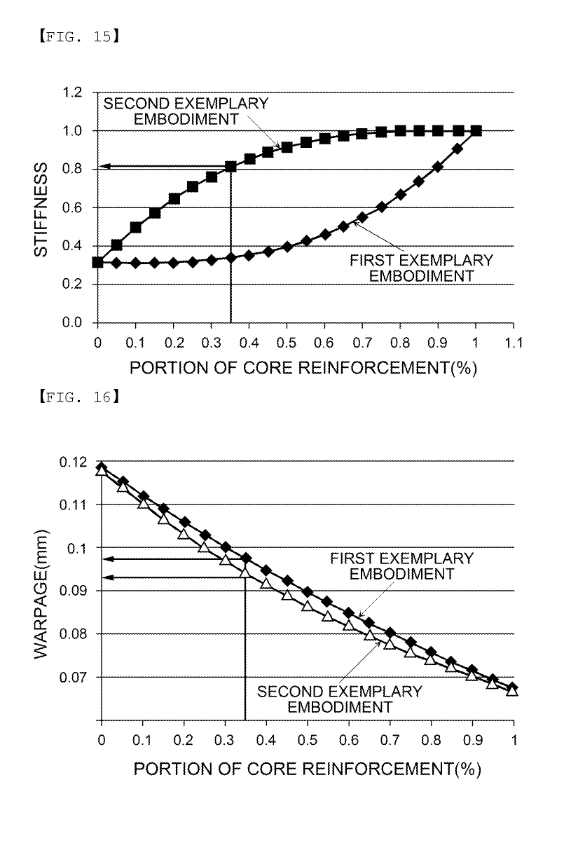

The printed circuit board configured according to the exemplary embodiment of the present invention is manufactured by the above-mentioned manufacturing process and the general printed circuit board according to the related art, that is, the printed circuit board manufactured using the insulating layer made of the insulating material without using the core reinforcement and the printed circuit board according to the exemplary embodiment of the present invention is applied with predetermined heat, and then a moduli of elasticity thereof are simulated below as illustrated in FIG. 14.

FIG. 14 is a warpage characteristic simulation graph of the printed circuit board according to the first exemplary embodiment of the present invention and the printed circuit board according to the related art. As illustrated in FIG. 14, in the printed circuit board according to the related art in which a prepreg material is inserted between the insulating layers, a modulus of elasticity which is a force causing warpage suddenly increases with the increase in temperature, but in the printed circuit board according to the exemplary embodiment of the present invention, since the change in the modulus of elasticity is not large at low temperature or high temperature and is maintained at a low level, it can be appreciated that the warpage occurrence during the process of manufacturing a printed circuit board is minimized. That is, the printed circuit board according to the exemplary embodiment of the present invention has the core reinforcement made of the glass material formed on the surface of the insulating layer forming the core or inserted between the insulating layers, such that it may have the excellent stiffness and have the minimized warpage due to the change in temperature and humidity which are applied during the process of manufacturing a printed circuit board.

Meanwhile, in order to implement the more improved stiffness and warpage characteristic of the core than in the printed circuit board according to the related art, the printed circuit board according to the exemplary embodiment of the present invention having technical features of the above-mentioned exemplary embodiments is preferably configured so that a portion occupied by the core reinforcement to the overall thickness of the core configured of the insulating layer and the core reinforcement ranges from 35% to 80%. This may be applied to both of the configurations which are adopted in the printed circuit board (FIG. 1) according to the first exemplary embodiment of the present invention and the printed circuit board (FIG. 6) according to the second exemplary embodiment of the present invention as described above.

Further, when the coefficient of thermal expansion (CTE) and the modulus of elasticity of the core reinforcement and the insulating layer configuring the core in each exemplary embodiment satisfy the following Equation 1, the warpage characteristic of the core may be more improved than in the printed circuit board according to the related art.

$$\frac{( α1 + α2 )}{( E 1 \times V 1 ) + ( E 2 \times ( 1 - V 1 ) )} = 6.492 \times {10}^{- 8} \sim 4.463 \times {10}^{- 6} / GPa \cdot k \qquad [ Equation 1 ]$$

where

α1: Coefficient of thermal expansion of the core reinforcement (1/k),

α2: Coefficient of thermal expansion of the insulating layer (1/k),

E1: Modulus of elasticity of the core reinforcement (GPa),

E2: Modulus of elasticity of the insulating layer (GPa).

Herein, the reason why the portion occupied by the core reinforcement to the overall thickness of the core is limited to at least 35% is that as compared with the core structure on the board according to the related art, when a configuration portion of the core reinforcement is 35% or more, the warpage characteristic of the core may be improved and the reason why the portion occupied by the core reinforcement to the overall thickness of the core is limited up to 80% or less is that the thickness of the insulating layer other than the core reinforcement in the core may be manufactured up to 10%. In this case, when the thickness of the insulating layer is formed to be thinner, cracks may occur in the core and a fracture of the core may occur due to the occurrence of cracks.

Therefore, the thickness of the core reinforcement in the overall thickness ranges from 35% to 80% based on the above Equation and when the core reinforcement and the insulating layer surrounding the core reinforcement satisfy a range of 6.492×10 to 4.463×10/GPa k by substituting variables of the insulating layer made of any one insulating material of various materials, that is, PPG, ABF, PI and primer or the insulating layer in which any one insulating material of PPG, ABF, PI and primer is impregnated with a glass cloth, a filler, and the like, into the above Equation, the warpage of the core may be improved.

When the portion occupied by the core reinforcement to the overall thickness of the core and the condition of the above Equation are satisfied, as illustrated in FIG. 15 or 16, the stiffness and the warpage characteristic of the core may be satisfied.

FIG. 15 is a stiffness characteristic simulation graph of the printed circuit board according to the first and second exemplary embodiments of the present invention and FIG. 16 is a warpage characteristic simulation graph of the printed circuit board according to the first and second exemplary embodiments of the present invention.

As illustrated in the graphs, reviewing FIGS. 15 and 16, the printed circuit boards according to the first and second exemplary embodiments of the present invention as described above are more improved in the stiffness and the warpage characteristic than in the core (mainly CCL) of the printed circuit board according to the related art when the portion occupied by the core reinforcement to the overall thickness of the core is 35% or more and it can be appreciated from each exemplary embodiment that when the portion occupied by the core reinforcement to the overall thickness of the core is 35% or more, the printed circuit board according to the second exemplary embodiment of the present invention may have the stiffness about 2.5 times as large as the printed circuit board according to the first exemplary embodiment of the present invention and may be slighter excellent in the warpage characteristic than in the printed circuit board according to the first exemplary embodiment of the present invention.

As set forth above, according to the printed circuit board and the method for manufacturing the same according to the exemplary embodiments of the present invention, the printed circuit board can be manufactured by inserting the core reinforcement in a film type of the glass having stiffness or the non-conductive polymer material thereinto to maintain the stiffness of the printed circuit board at high temperature, thereby preventing the board from being warped during the manufacturing process of the board.

Further, according to the exemplary embodiments of the present invention, even though the printed circuit board in a thin plate type is manufactured, since the stiffness of the core reinforcement is maintained, the deflection of the printed circuit board can be improved and the heat radiating characteristic in the vertical direction can be improved.

Although the preferred embodiments of the present invention have been disclosed for illustrative purposes, those skilled in the art will appreciate that various modifications, additions and substitutions are possible, without departing from the scope and spirit of the invention as disclosed in the accompanying claims. Accordingly, such modifications, additions and substitutions should also be understood to fall within the scope of the present invention.

1. A printed circuit board comprising:
core having insulating layers and a core reinforcement alternately laminated therein.

2. The printed circuit board according to claim 1, wherein the core is configured so that the core reinforcement is inserted between the insulating layers.

3. The printed circuit board according to claim 1, wherein the core is configured so that the core reinforcement is laminated on both surfaces of the insulating layer.

4. The printed circuit board according to claim 1, wherein the core reinforcement is made of a plate-shaped glass material.

5. The printed circuit board according to claim 1, wherein the core reinforcement is formed in a film type of a non-conductive polymer material.

6. The printed circuit board according to claim 2, wherein the core reinforcement is formed at a thickness of 25 to 200 μm.

7. The printed circuit board according to claim 3, wherein the insulating layer is formed of a plurality of insulating layers.

8. The printed circuit board according to claim 1, wherein a portion of a thickness of the core reinforcement to the overall thickness of the core ranges from 35% to 80%.

9. The printed circuit board according to claim 1, wherein the core is configured to satisfy the following Equation for a warpage characteristic in a relationship of a coefficient of thermal expansion (CTE) and a modulus of elasticity between the core reinforcement and the insulating layer.
$$\frac{( α1 + α2 )}{( E 1 \times V 1 ) + ( E 2 \times ( 1 - V 1 ) )} = 6.492 \times {10}^{- 8} \sim 4.463 \times {10}^{- 6} / GPa \cdot k \qquad Equation$$
where
α1: Coefficient of thermal expansion of the core reinforcement (1/k),
α1: Coefficient of thermal expansion of the insulating layer (1/k),
E1: Modulus of elasticity of the core reinforcement (GPa),
E2: Modulus of elasticity of the insulating layer (GPa).

10. A printed circuit board, comprising:
a core reinforcement having stiffness;
insulating layers formed on both surfaces of the core reinforcement;
a through hole formed by penetrating through the insulating layer and the core reinforcement; and
a circuit layer formed on the insulating layer and a plating layer formed in the through hole for implementing inter-layer connection of the circuit layers.

11. The printed circuit board according to claim 10, wherein a coating layer is further disposed on a surface of the core reinforcement between the insulating layers.

12. The printed circuit board according to claim 11, wherein the coating layer is formed at a thickness of 2 μm or less.

13. The printed circuit board according to claim 10, wherein the core reinforcement is formed in a film type of plate-shaped glass or a non-conductive polymer material.

14. The printed circuit board according to claim 10, wherein the insulating layer is made of an insulating material in which a glass fabric is impregnated.

15. The printed circuit board according to claim 10, wherein the core reinforcement is formed at a thickness of 25 to 200 μm.

16. The printed circuit board according to claim 10, wherein a portion of a thickness of the core reinforcement to a thickness of the core reinforcement and the insulating layer ranges from 35% to 80%.

17. A method for manufacturing a printed circuit board, comprising:
preparing a core reinforcement;
forming insulating layers on both surfaces of the core reinforcement;
forming a through hole penetrating through the core reinforcement and the insulating layers; and
forming a plating layer in the through hole and forming a circuit layer on a surface of the insulating layer.

18. The method according to claim 17, wherein the core reinforcement is formed in a film type of plate-shaped glass having stiffness or a non-conductive polymer material.

19. The method according to claim 17, further comprising:
prior to the forming of the insulating layer, forming a coating layer on one surface or both surfaces of the core reinforcement.

20. The method according to claim 19, wherein the coating layer is formed at a thickness of 2 μm or less.

21. The method according to claim 17, further comprising:
prior to forming the through hole, forming a metal thin film on the insulating layer.

22. The method according to claim 21, wherein the metal thin film is formed simultaneously with forming the insulating layer on the surface of the core reinforcement.

23. The method according to claim 17, wherein the plating layer is formed by electrolytic copper plating and formed simultaneously with forming a plating layer for forming the circuit layer formed on the insulating layer.

24. A printed circuit board, comprising:
an insulating layer;
core reinforcements laminated on both surfaces of the insulating layer;
a through hole formed by penetrating through the insulating layer and the core reinforcement; and
a circuit layer formed on the core reinforcement.

25. The printed circuit board according to claim 24, wherein the insulating layer is formed of a plurality of insulating layers.

26. The printed circuit board according to claim 24, wherein a portion of a thickness of the core reinforcement to a thickness of the core reinforcement and the insulating layer ranges from 35% to 80%.

27. The printed circuit board according to claim 24, wherein the core reinforcement is formed in a film type of plate-shaped glass or a non-conductive polymer material.

28. The printed circuit board according to claim 24, wherein the insulating layer is made of an insulating material in which a glass fabric is impregnated.

29. The printed circuit board according to claim 24, wherein the circuit layer includes:
a seed layer formed on the core reinforcement; and
a plating layer formed on the seed layer.

30. The printed circuit board according to claim 29, wherein the seed layer is made of any one selected from the group consisting of conductive metal materials of titanium (Ti), copper (Cu), molybdenum (Mo), nickel (Ni), silver (Ag), zinc (Zn), and carbon (C) or an alloy thereof.

31. A method for manufacturing a printed circuit board, comprising:
bonding core reinforcements to both surfaces of an insulating layer;
forming a seed layer on the core reinforcement;
forming a plating resist layer having an opening for forming a circuit on the seed layer;
forming a plating layer in the opening for forming the circuit; and
forming the circuit layer by removing the plating resist layer.

32. The method according to claim 31, wherein in the bonding of the core reinforcement to the insulating layer, the core reinforcements are disposed on both surfaces of the insulating layer; and
the insulating layer is bonded to the core reinforcement by heating and pressing the core reinforcement.

33. The method according to claim 31, further comprising:
prior to the forming of the seed layer, processing a through hole penetrating through the insulating layer and the core reinforcement.

34. The method according to claim 33, further comprising:
after the processing of the through hole, cleaning a surface of the core reinforcement and an inner wall of the through hole.

35. The method according to claim 31, wherein the core reinforcement is formed in a film type of plate-shaped glass having stiffness or a non-conductive polymer material.

36. The method according to claim 34, wherein the cleaning is performed by dry etching or wet etching.

37. The printed circuit board according to claim 10, wherein a warpage characteristic satisfies the following Equation in a relationship of a coefficient of thermal expansion (CTE) and a modulus of elasticity between the core reinforcement and the insulating layer.
$$\frac{( α1 + α2 )}{( E 1 \times V 1 ) + ( E 2 \times ( 1 - V 1 ) )} = 6.492 \times {10}^{- 8} \sim 4.463 \times {10}^{- 6} / GPa \cdot k \qquad Equation$$
where
α1: Coefficient of thermal expansion of the core reinforcement (1/k),
α2: Coefficient of thermal expansion of the insulating layer (1/k),
E1: Modulus of elasticity of the core reinforcement (GPa),
E2: Modulus of elasticity of the insulating layer (GPa).

38. The printed circuit board according to claim 1, wherein the upper and lower surfaces of the core which the insulating layers and the core reinforcements are alternately laminated with are laminated with second insulating layers, circuit layers are built up on the second insulating layers, the circuit layers are conducted through via holes formed on the second insulating layers, and solder resist layers are formed on the second insulating layers.

39. The printed circuit board according to claim 3, wherein the core reinforcement is formed at a thickness of 25 to 200 μm.

40. The printed circuit board according to claim 24, wherein a warpage characteristic satisfies the following Equation in a relationship of a coefficient of thermal expansion (CTE) and a modulus of elasticity between the core reinforcement and the insulating layer.
$$\frac{( α1 + α2 )}{( E 1 \times V 1 ) + ( E 2 \times ( 1 - V 1 ) )} = 6.492 \times {10}^{- 8} \sim 4.463 \times {10}^{- 6} / GPa \cdot k \qquad Equation$$
where
α1: Coefficient of thermal expansion of the core reinforcement (1/k),
α2: Coefficient of thermal expansion of the insulating layer (1/k),
E1: Modulus of elasticity of the core reinforcement (GPa),
E2: Modulus of elasticity of the insulating layer (GPa).

41. The printed circuit board according to claim 10, wherein the upper and lower surfaces of the core which the insulating layers and the core reinforcements are alternately laminated with are laminated with second insulating layers, circuit layers are built up on the second insulating layers, the circuit layers are conducted through via holes formed on the second insulating layers, and solder resist layers are formed on the second insulating layers.

42. The printed circuit board according to claim 24, wherein the upper and lower surfaces of the core which the insulating layers and the core reinforcements are alternately laminated with are laminated with second insulating layers, circuit layers are built up on the second insulating layers, the circuit layers are conducted through via holes formed on the second insulating layers, and solder resist layers are formed on the second insulating layers.
